(19) United States
(12) Patent Application Publication
(10) Pub. No.: US 2010/0208538 A1
(43) Pub. Date: Aug. 19, 2010

(54) SENSING CIRCUIT FOR SEMICONDUCTOR MEMORY

(75) Inventors: Amit Kumar Gupta, Aligarh (IN); Devesh Dwivedi, Bangalore (IN); Sanjeev Kumar Jain, Ghaziabad (IN); Yatender Mishra, Pitam Pura (IN)

Correspondence Address: ONDA TECHNO Intl. Patent Attys., 12-1 Omiya-cho 2-chome, Gifu City, 500-8731, JP

(73) Assignee: FREESCALE SEMICONDUCTOR, INC., Austin, TX (US)

(21) Appl. No.: 12/620,539

(22) Filed: Nov. 17, 2009

(30) Foreign Application Priority Data
Feb. 17, 2009 (IN) 303/DEL/2009

(51) Int. Cl. G11C 7/00

(52) U.S. Cl. 365/203; 365/205; 365/189.02

(57) ABSTRACT

A sensing circuit for a semiconductor memory includes a multiplexer coupled to a bit line and a data line coupling the multiplexer to a sense amplifier. The data line is configured to be precharged to a voltage level higher than a precharge voltage level of the bit line.

### BACKGROUND OF THE INVENTION

The present invention relates generally to semiconductor memories and more particularly to a sensing circuit for semiconductor memories.

Sensing is very slow when a semiconductor memory using ultra-deep sub-micron (UDSM) technology nodes under 45 nanometers (nm) is operated at a lower end of its allowable voltage range. Access and cycle times of high density non-banked memory are also much slower when such memory is operated at a lower end of its allowable voltage range due to large bit line capacitance.

Memory speeds may be increased by memory banking. However, one downside to this is that banked memory generally requires a larger area.

In view of the foregoing, it would be desirable to have a faster sensing circuit for high density and high speed semiconductor memories.

### BRIEF DESCRIPTION OF THE DRAWINGS

The following detailed description of a preferred embodiment of the invention will be better understood when read in conjunction with the appended drawings. The present invention is illustrated by way of example and is not limited by the accompanying figures.

FIG. 1 is a schematic block diagram of a portion of a semiconductor memory in accordance with an exemplary embodiment of the present invention;

FIG. 2 is a schematic circuit diagram illustrating a sensing circuit for the semiconductor memory of FIG. 1; and

FIG. 3 is a timing diagram illustrating an operation to read a selected memory cell storing a LOW logic value with the sensing circuit of FIG. 2.

### DETAILED DESCRIPTION OF THE INVENTION

The detailed description set forth below in connection with the appended drawings is intended as a description of the presently preferred embodiment of the invention, and is not intended to represent the only form in which the present invention may be practiced. It is to be understood that the same or equivalent functions may be accomplished by different embodiments that are intended to be encompassed within the spirit and scope of the invention.

The present invention is directed to a sensing circuit for a semiconductor memory including a multiplexer coupled to a bit line and a data line coupling the multiplexer to a sense amplifier. The data line is configured to be precharged to a voltage level higher than a precharge voltage level of the bit line.

The present invention is also directed to a semiconductor memory including a plurality of memory cells electrically connected in a matrix arrangement to a plurality of word lines and a plurality of bit lines. A first precharge circuit is configured to precharge the bit lines to a first voltage level. A multiplexer is coupled to the bit lines. A data line couples the multiplexer to a sense amplifier. A second precharge circuit is configured to precharge the data line to a second voltage level that is higher than the first voltage level.

The sensing circuit of the present invention has several advantages. In particular, by precharging the data line to a voltage level higher than the precharge voltage level of the bit line, the time required for the data line to discharge down to the input threshold voltage of the sense amplifier is reduced and consequently, the access and cycle times for the semiconductor memory are shortened. Further, the sensing circuit of the present invention is able to achieve speeds faster than or comparable to conventional high speed memories without banking and at increased memory cell densities.

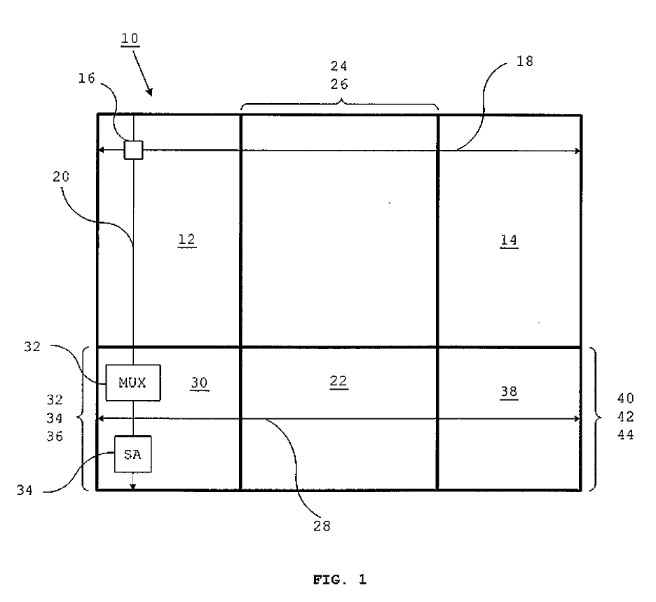

Referring now to FIG. 1, a schematic block diagram of a portion of a semiconductor memory 10 in accordance with an exemplary embodiment of the present invention is shown.

The semiconductor memory 10 includes a first memory array 12 and a second memory array 14. Each of the first and second memory arrays 12 and 14 includes a plurality of memory cells 16 electrically connected in a matrix arrangement to a plurality of word lines 18 and a plurality of bit lines 20. For clarity purposes, not all the memory cells 16, word lines 18 and bit lines 20 are shown in FIG. 1. Nonetheless, as will be understood by those of ordinary skill in the art, the first and second memory arrays 12 and 14 may have any desired number of memory cells 16, word lines 18 and bit lines 20.

The first and second memory arrays 12 and 14 share and are coupled to control circuitry 22 via a plurality of row decoders 24 and a plurality of word line drivers 26. A precharge line 28 receives a precharge signal PRCH from the control circuitry 22. The control circuitry 22, row decoders 24 and word line drivers 26 are well known to those of ordinary skill in the art. Therefore, detailed description thereof is not required for a complete understanding of the present invention.

The first memory array 12 is coupled to a first input/output (IO) section 30 including a plurality of column multiplexers 32, a plurality of sense amplifiers 34 and a plurality of IO buffers 36. Similarly, the second memory array 14 is coupled to a second IO section 38 including a plurality of column multiplexers 40, a plurality of sense amplifiers 42 and a plurality of IO buffers 44. For clarity purposes, only one (1) column multiplexer 32 and one (1) sense amplifier 34 are illustrated in FIG. 1. Nonetheless, as will be understood by those of ordinary skill in the art, the first and second IO sections 30 and 38 may have any desired number of column multiplexers 32 and 40 and sense amplifiers 34 and 42, depending, for example, on the number of word lines 18 and bit lines 20 in the first and second memory arrays 12 and 14.

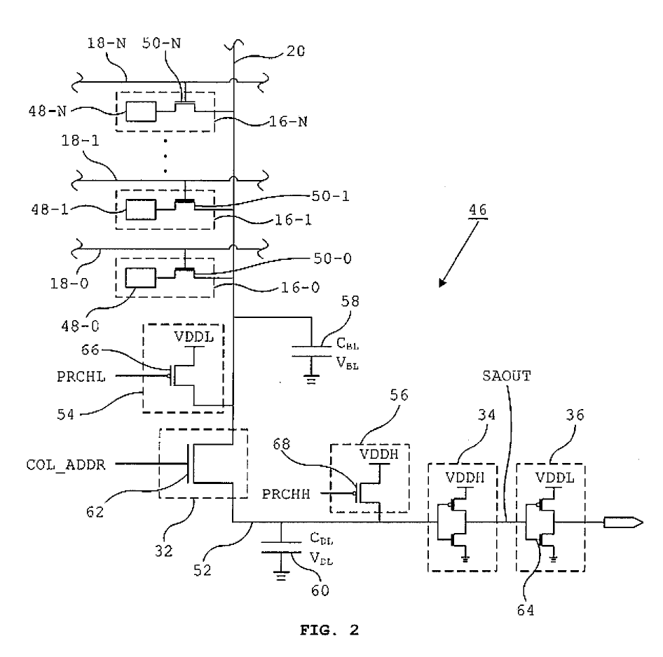

A sensing circuit used by the semiconductor memory 10 will now be described in greater detail below with reference to FIG. 2.

Referring to FIG. 2, a schematic circuit diagram illustrating a sensing circuit 46 for the semiconductor memory 10 of FIG. 1 is shown. In the illustrated embodiment of FIG. 2, a single column of memory cells 16-0 through 16-N is shown. Each memory cell 16-0 through 16-N includes a storage cell 48-0 through 48-N and an access transistor 50-0 through 50-N that couples the associated storage cell 48-0 through 48-N to a common bit line 20. Each access transistor 50-0 through 50-N has a gate connected to an associated word line 18-0 through 18-N.

In one embodiment, each of the storage cells 48-0 through 48-N may comprises a capacitor having a first plate coupled to the associated access transistor 50-0 through 50-N and a second plate that is either grounded or ungrounded, depending on the logic state of the memory cell 16-0 through 16-N. Nevertheless, it should be understood that the storage cells 48-0 through 48-N are not limited to the configuration described. Other storage cell configurations known to those of ordinary skill in the art may be employed in alternative embodiments of the invention.

The sensing circuit 46 includes a column multiplexer 32 coupled to the bit line 20, a sense amplifier 34 coupled to the column multiplexer 32 via a data line 52, and an IO buffer 36 coupled to the sense amplifier 34. A first precharge circuit 54 is coupled to the bit line 20 and is configured to precharge the bit line 20 to a first voltage level VDDL. A second precharge circuit 56 is coupled to the data line 52 and is configured to precharge the data line 52 to a second, higher voltage level VDDH. Each of the bit line 20 and the data line 52 has an associated line capacitance illustrated as bit line capacitor 58 and data line capacitor 60, respectively.

In the embodiment shown, the column multiplexer 32 includes an n-type transistor 62 having a gate configured to receive a column address signal COL_ADDR, a drain coupled to the bit line 20 and a source coupled to the data line 52. Advantageously, the use of the n-type transistor 62 in the column multiplexer 32 results in area savings since the n-type transistor 62 consumes less area than a transmission gate or a p-type transistor commonly employed in conventional multiplexers. Nevertheless, it should be understood that the present invention is not limited by the type of device employed in the column multiplexer 32. The column multiplexer 32 may, for example, employ a p-type transistor with a gate that is activated by an active low pulse in an alternative embodiment.

The column multiplexer 32 is configured to act as a charge transfer device thereby allowing VDDH to fall at a faster rate than VDDL, thereby increasing speed. In the present embodiment, the column multiplexer 32 may be configured to operate at least one multiplexer threshold voltage Vₜₕ higher than the precharge voltage level VDDL of the bit line 20 so that charge transfer can begin immediately once the n-type transistor 62 of the column multiplexer 32 is switched on. Thus, for example, if the threshold voltage Vₜₕ of the n-type transistor 62 is 0.2 volt (V) and the precharge voltage level VDDL of the bit line 20 is 1.0 V, then the column multiplexer 32 may be configured to operate at least 1.2 V. Advantageously, this allows the sensing circuit 46 to achieve speed advantages over the full operating voltage range of the semiconductor memory 10. In one embodiment, the column multiplexer 32 may comprise a low threshold voltage device or a standard threshold voltage device so that the sensing circuit 46 may be operated at a lower voltage domain. In the embodiment where the column multiplexer 32 comprises a p-type transistor (i.e. the column multiplexer 32 is turned on by a gate voltage of 0 V), the column multiplexer 32 may be configured to operate at less than one multiplexer threshold voltage Vₜₕ higher than the precharge voltage level VDDL of the bit line 20.

The first voltage level VDDL may be provided by a primary voltage source within the semiconductor memory 10 and the second voltage level VDDH may be provided by a secondary voltage source. In the present context, the term “primary voltage source” may be defined as the voltage source to which a majority of the transistors in the semiconductor memory 10 are connected. The term “secondary voltage source” may be likewise defined as the voltage source to which a minority of the transistors in the semiconductor memory 10 are connected. The secondary voltage VDDH may be generated on-chip using, for example, charge pump circuitry or provided via an externally controlled voltage supply.

The first voltage level VDDL may be between about 0.8 V and about 1.3 V. In the present embodiment, the second voltage level VDDH may be at least one multiplexer threshold voltage Vₜₕ higher than the first voltage level VDDL. For example, if the threshold voltage Vₜₕ of the n-type transistor 62 of the column multiplexer 32 is about 0.2 V and the first voltage level VDDL is between about 0.8 V and about 1.3 V, the second voltage level VDDH may be between about 1.0 V and about 1.5 V. Advantageously, this minimizes the number of voltage sources required by the semiconductor memory 10 and thus simplifies the circuit design. In general, the greater the difference between the first voltage level VDDL and the second voltage level VDDH, the faster the speed of the semiconductor memory 10. The second voltage level VDDH is however constrained by the breakdown voltages of the transistors employed in the sensing circuit 46.

The sense amplifier 34 may be implemented using any known sense amplifier circuitry. Accordingly, detailed description of the sense amplifier 34 is not required for a complete understanding of the present invention. In the present embodiment, the sense amplifier 34 is configured to operate in a voltage domain higher than the precharge voltage level VDDL of the bit line 20. By operating the sense amplifier 34 in a higher voltage domain, the sensitivity of the sense amplifier 34 to voltage fluctuations may be reduced. This improves the reliability of the semiconductor memory 10 and, consequently, manufacturing yield.

In the present embodiment, the IO buffer 36 includes an inverter circuit 64. As shown in FIG. 2, the inverter circuit 64 is configured to switch an output SAOUT of the sense amplifier 34 between the first voltage level VDDL and ground, that is zero (0) potential.

In the embodiment shown, each of the first and second precharge circuits 54 and 56 includes a p-type transistor: first p-type transistor 66 and second p-type transistor 68, respectively. Each of the first and second p-type transistors 66 and 68 has a gate configured to receive a precharge signal: first precharge signal PRCHL and second precharge signal PRCHH, respectively. The first precharge signal PRCHL may be operable in the primary voltage VDDL domain and the second precharge signal PRCHH may be operable in the secondary voltage VDDH domain. A source of the first p-type transistor 66 is coupled to a voltage source at the first voltage level VDDL and a drain of the first p-type transistor 66 is coupled to the bit line 20. A source of the second p-type transistor 68 is coupled to a voltage source at the second voltage level VDDH and a drain of the second p-type transistor 68 is coupled to the data line 52.

The operation of the sensing circuit 46 will now be described.

The column of memory cells 16-0 through 16-N in FIG. 2 is prepared for a read operation by precharging the bit line 20 to the first voltage level VDDL and the data line 52 to the second voltage level VDDH.

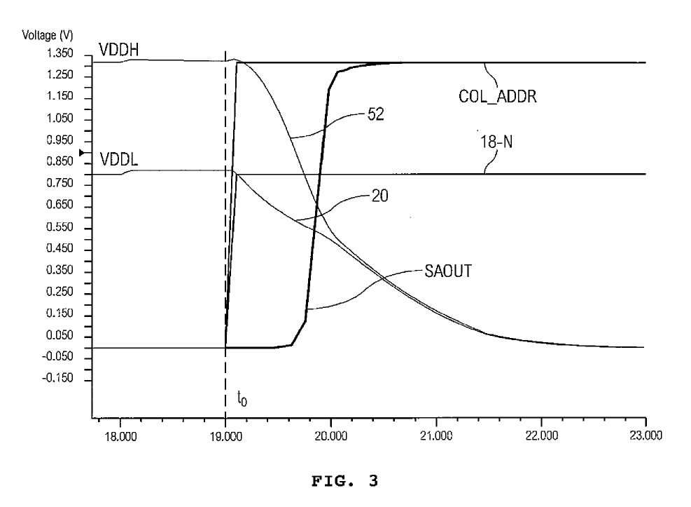

Referring now to FIG. 3, a timing diagram illustrating an operation to read a selected memory cell 16-N storing a LOW logic value with the sensing circuit 46 of FIG. 2 is shown.

At t₀, the operation to read the selected memory cell 16-N is initiated by activating the associated word line 18-N and switching ON the n-type transistor 62 with a column address signal COL_ADDR in the high voltage domain VDDH.

Activation of the word line 18-N switches ON the associated access transistor 50-N connecting the selected memory cell 16-N to the precharged bit line 20. Further, because the selected memory cell 16-N in the described embodiment stores a LOW logic value, activation of the word line 18-N causes the selected memory cell 16-N to discharge the bit line 20 through the associated access transistor 50-N.

Due to differences in the line capacitance (represented by bit line capacitor 58 and data line capacitor 60 in FIG. 2) and the precharge voltage levels (VDDL and VDDH, respectively) of the bit line 20 and the data line 52 to which the n-type transistor 62 is connected, the column multiplexer 32 operates as a charge transfer device when switched ON.

The selected memory cell 16-N may be read when the voltage level on the data line 52 drops below an input threshold voltage of the sense amplifier 34 as this causes the output SAOUT of the sense amplifier 34 to transition from a LOW state to a HIGH state. Accordingly, the time required for the data line 52 to discharge down to the input threshold voltage of the sense amplifier 34 is a factor limiting the speed of the read operation, and consequently the speed of the semiconductor memory 10. In the present embodiment, the discharge time of the data line 52 is reduced by precharging the data line 52 to a voltage level VDDH higher than the precharge voltage level VDDL of the bit line 20, as explained below with reference to the following equations.

Assuming the voltage V_{BL} across the bit line capacitor 58 drops by a voltage V₁ during the operation to read a LOW logic value from the selected memory cell 16-N, the final voltage V_{f} across each of the bit line capacitor 58 and the data line capacitor 60 may be expressed by the following equation:

$${V}_{f} \frac{⌊ {C}_{BL} \times ( {V}_{BL} - {V}_{1} ) + {C}_{DL} \times {V}_{DL} ⌋}{( {C}_{BL} + {C}_{DL} )} \qquad ( 1 )$$

where C_{BL} represents the line capacitance associated with the bit line 20, C_{DL} represents the line capacitance associated with the data line 52, and V_{DL} represents the voltage across the data line capacitor 60.

Assuming also that V_{DL} drops by a voltage V₂, V₂ may be expressed by the following equation:

V₂=V_{DL}−V_{f} (2)

Substituting equation (1) into equation (2), V₂ may be expressed as follows:

$$\begin{matrix}{V}_{2} = Cr \times ( K + {V}_{1} ) where & ( 3 ) \\ Cr = \frac{{C}_{BL}}{( {C}_{BL} + {C}_{DL} )} and & ( 4 ) \\ K = {V}_{DL} - {V}_{BL} & ( 5 )\end{matrix}$$

Since C_{BL} is substantially greater than C_{DL}, and V_{DL} equals VDDH and V_{BL} equals VDDL in the present embodiment, Cr approximates the value one (1) and K is greater than zero (0). Consequently, V₂ is greater than V₁. This causes the voltage V_{DL} across the data line capacitor 60 to fall more quickly than the voltage V_{BL} across the bit line capacitor 58, as can be seen from FIG. 3. Accordingly, the discharge time of the data line 52 is reduced. This in turn increases the speed of the read operation, resulting in faster access and cycle times for the semiconductor memory 10.

Further, as evident from equations (3) and (4), the sensing circuit 46 of the present embodiment is relatively insensitive to the magnitude of the bit line capacitance C_{BL}. Advantageously, this allows a memory designer to increase the density of the semiconductor memory 10 by adding more memory cells 16 per column without compromising the speed of the semiconductor memory 10.

The sensing circuit 46 may be implemented in any feasible device, using any feasible circuit technology and any feasible manufacturing process.

Although illustrated as being coupled to only one (1) bit line 20 in FIGS. 1 and 2, it should be understood that the present invention is not limited by the number of bit lines 20 to which each of the column multiplexers 32 and 40 may be connected. As will be understood by those of ordinary skill in the art, each of the column multiplexers 32 and 40 may be coupled to one or more bit lines 20. For example, the column multiplexers 32 and 40 may be 4-to-1 and/or 8-to-1 multiplexers.

A simulation was performed with memories of different densities at different voltage settings for a worst case scenario, that is, at a slow-slow corner of a semiconductor memory operating at 0.9 V and 125 degrees Celsius (° C.). The results of the simulation are set out in Table 1 below.

TABLE 1

| | No. of Rows | | |
|---|---|---|---|
| VDDH/VDDL | 128 | 256 | 512 |
| VDDH = VDDL = 0.8 V | 3.32 ns | 5.45 ns | 9.35 ns |
| VDDH = 0.9 V VDDL = 0.8 V | 2.87 ns | 4.63 ns | 7.84 ns |
| VDDH = 1.0 V VDDL = 0.8 V | 2.46 ns | 3.90 ns | 6.53 ns |
| VDDH = 1.1 V VDDL = 0.8 V | 2.11 ns | 3.26 ns | 5.29 ns |
| VDDH = 1.2 V VDDL = 0.8 V | 1.80 ns | 2.67 ns | 4.17 ns |
| VDDH = 1.3 V VDDL = 0.8 V | 1.43 ns | 2.01 ns | 2.91 ns |

As can be seen from Table 1, faster or comparable speeds may be achieved with higher density memories employing the present invention than with conventional high speed memories.

An exemplary calculation of the area required by a high speed memory as opposed to that required by a high density memory is shown in Table 2 below.

TABLE 2

| | | |
|---|---|---|
| | High Speed | High Density |
| Parameters | Memory | Memory |

| | | | |
|---|---|---|---|
| Y (μm) | Array | 200.7 | 200.7 |
| Y (μm) | Control_repeater | 98 | 33.6 |
| Y (μm) | Control | 21 | 21 |
| X (μm) | IO + Control | 492.8 | 492.8 |
| Total (μm) | Y | 319.7 | 255.3 |
| Total (μm) | X | 492.8 | 492.8 |
| Area (μm²) | X * Y | 157550.1 | 125813.8 |

As can be seen from Table 2, the high density memory consumes much less (approximately 25% less) area than the high speed memory.

It follows from the foregoing that the sensing circuit of the present invention is able to achieve speeds faster than or comparable to conventional high speed memories without banking and even at increased memory cell densities.

The description of the preferred embodiment of the present invention has been presented for purposes of illustration and description, but is not intended to be exhaustive or to limit the invention to the form disclosed. It will be appreciated by those skilled in the art that changes could be made to the embodiment described above without departing from the broad inventive concept thereof. For example, those of ordinary skill in the art will understand that the present invention is not limited to the described memory structure, and may be applied to various types of semiconductor memories including, but not limited to, static random access memory (SRAM), read only memory (ROM), register files, and other types of memory applications. It is understood, therefore, that this invention is not limited to the particular embodiment disclosed, but covers modifications within the spirit and scope of the present invention as defined by the appended claims.

1. A sensing circuit for a semiconductor memory, comprising:
a multiplexer coupled to a bit line; and
a data line coupling the multiplexer to a sense amplifier, wherein the data line is configured to be precharged to a voltage level higher than a precharge voltage level of the bit line.

2. The sensing circuit for a semiconductor memory of claim 1, wherein the multiplexer is configured to operate at least one multiplexer threshold voltage higher than the precharge voltage level of the bit line.

3. The sensing circuit for a semiconductor memory of claim 2, wherein the multiplexer includes one of a group comprising a low threshold voltage device and a standard threshold voltage device.

4. The sensing circuit for a semiconductor memory of claim 1, wherein the multiplexer comprises an n-type transistor.

5. The sensing circuit for a semiconductor memory of claim 4, wherein a gate of the n-type transistor is configured to receive a column address signal, a drain of the n-type transistor is coupled to the bit line, and a source of the n-type transistor is coupled to the data line.

6. The sensing circuit for a semiconductor memory of claim 1, wherein the sense amplifier is configured to operate in a voltage domain higher than the precharge voltage level of the bit line.

7. The sensing circuit for a semiconductor memory of claim 1, further comprising a precharge circuit coupled to the data line.

8. The sensing circuit for a semiconductor memory of claim 7, wherein the precharge circuit comprises a p-type transistor.

9. The sensing circuit for a semiconductor memory of claim 8, wherein a source of the p-type transistor is coupled to a voltage source and a drain of the p-type transistor is coupled to the data line.

10. The sensing circuit for a semiconductor memory of claim 9, wherein the voltage source is at least one multiplexer threshold voltage higher than the precharge voltage level of the bit line.

11. A semiconductor memory, comprising:
a plurality of memory cells electrically connected in a matrix arrangement to a plurality of word lines and a plurality of bit lines;
a first precharge circuit configured to precharge the bit lines to a first voltage level;
a multiplexer coupled to the bit lines;
a sense amplifier;
a data line coupling the multiplexer to the sense amplifier; and
a second precharge circuit configured to precharge the data line to a second voltage level, wherein the second voltage level is higher than the first voltage level.

12. The semiconductor memory of claim 11, wherein the multiplexer is configured to operate at least one multiplexer threshold voltage higher than the first voltage level.

13. The semiconductor memory of claim 12, wherein the multiplexer includes one of a group comprising a low threshold voltage device and a standard threshold voltage device.

14. The semiconductor memory of claim 11, wherein the multiplexer comprises an n-type transistor.

15. The semiconductor memory of claim 14, wherein a gate of the n-type transistor is configured to receive a column address signal, a drain of the n-type transistor is coupled to the bit line, and a source of the n-type transistor is coupled to the data line.

16. The semiconductor memory of claim 11, wherein the sense amplifier is configured to operate in a voltage domain higher than the first voltage level.

17. The semiconductor memory of claim 11, wherein the second voltage level is at least one multiplexer threshold voltage higher than the first voltage level.

18. The semiconductor memory of claim 11, further comprising a buffer coupled to the sense amplifier.

19. The semiconductor memory of claim 18, wherein the buffer comprises an inverter circuit.

20. The semiconductor memory of claim 19, wherein the inverter circuit is configured to switch an output of the sense amplifier between the first voltage level and ground.
